(19) United States
(12) Patent Application Publication
(10) Pub. No.: US 2012/0319623 A1
(43) Pub. Date: Dec. 20, 2012

(54) LEAD LINE STRUCTURE AND DISPLAY PANEL HAVING THE SAME

(75) Inventors: Keng-Chuan Cheng, Chiayi City (TW); Chien-Hao Fu, New Taipei City (TW)

(73) Assignee: AU OPTRONICS CORPORATION, Hsinchu (TW)

(21) Appl. No.: 13/312,996

(22) Filed: Dec. 7, 2011

(30) Foreign Application Priority Data
Jun. 16, 2011 (TW) 100121047

(51) Int. Cl. H05B 37/00; H05K 1/00

(52) U.S. Cl. 315/312; 174/250

(57) ABSTRACT

A display panel having a display region and a non-display region is described. The display panel includes a pixel array, at least one driving device and a plurality of lead lines. The pixel array is disposed in the display region. The driving device is disposed in the non-display region. The lead lines are disposed in the non-display region and are electrically connected to the pixel array and the driving device. The lead lines are arranged into at least one fan-out structure between the pixel array and the driving device. In particular, the (n-1)th lead line has a pitch Pn-1=Wn-1+S, n is an integer larger than 1, Wn-1 represents a line width of the (n-1)th lead line, S represents a space between the adjacent lead lines, and the pitches P1˜Pn-1 of the plurality of lead lines are not completely the same.

### CROSS-REFERENCE TO RELATED APPLICATION

This application claims the priority benefit of Taiwan application serial no. 100121047, filed on Jun. 16, 2011. The entirety of the above-mentioned patent application is hereby incorporated by reference herein and made a part of this specification.

### BACKGROUND OF THE INVENTION

1. Field of the Invention

The present invention relates to a lead line structure and a display panel having the same.

2. Description of Related Art

In general, a liquid crystal display (LCD) panel of an LCD includes a pixel array substrate, a color filter array substrate, and a liquid crystal layer sandwiched by the two substrates. In the pixel array substrate, pads and lead lines are disposed in a non-display region, such that the pixel array and the driving chip are electrically connected to each other.

In order to match the contacts on the driving chip, the leads lines between the pixel array and the driving chip are arranged into a fan-out structure. However, resistances of these lead lines are not identical because the lengths of the lead lines in an edge region of the fan-out structure and the lengths of the lead lines in a middle of the fan-out structure are different. As a result, signals transmitted on the lead lines in the edge region and signals transmitted on the lead lines in the middle have obvious delay differences.

In addition, as slim border display panels are developed, how to reduce the length or the area of the fan-out structure so as to reduce the width of a non-display region of the display panel is also important.

### SUMMARY OF THE INVENTION

Accordingly, the present invention is directed to a lead line structure and a display panel having the same capable of reducing signal delay differences between the lead lines and narrowing the length of the fan-out structure.

A display panel having a display region and a non-display region is provided. The display panel includes a pixel array, at least one driving device and a plurality of lead lines. The pixel array is disposed in the display region. The driving device is disposed in the non-display region. The lead lines are disposed in the non-display region and are electrically connected to the pixel array and the driving device. The lead lines are arranged into at least one fan-out structure between the pixel array and the driving device. In particular, the (n-1)th lead line has a pitch P−1=Wn-1+S, n is an integer larger than 1, Wn-1 represents a line width of the (n-1)th lead line, S represents a space between the adjacent lead lines, and the pitches P1˜Pn-1 of the plurality of lead lines are not completely the same.

The present invention provides a lead line structure comprising a substrate and a plurality of lead lines disposed on the substrate and arranged into at least one fan-out structure, wherein the (n-1)th lead line has a pitch Pn-1=Wn-1+S, n is an integer larger than 1, Wn-1 represents a line width of the (n-1)th lead line, S represents a space between the adjacent lead lines, and the pitches P1˜Pn-1 of the plurality of lead lines are not completely the same.

In light of the foregoing, the pitches of the plurality of lead lines in the fan-out structure are not completely the same, and thus signal delay differences between the lead lines in the edge region and the lead lines in the middle of the fan-out structure are decreased. In addition, the lead line structure may further reduce the overall length of the lead line structure, such that it is beneficial to be applied in the slim border display panels.

In order to make the aforementioned and other features and advantages of the present invention more comprehensible, several embodiments accompanied with figures are described in detail below.

### BRIEF DESCRIPTION OF THE DRAWINGS

The accompanying drawings constituting a part of this specification are incorporated herein to provide a further understanding of the invention. Here, the drawings illustrate embodiments of the invention and, together with the description, serve to explain the principles of the invention.

FIG. 1 is a schematic top view showing a display panel according to an embodiment of the present invention.

FIG. 2 is a schematic diagram showing a lead line structure of the display panel of FIG. 1.

FIG. 3 is a schematic enlarging diagram of a region R in FIG. 2.

FIG. 4A and FIG. 4B are schematic diagrams showing lead line structures of a display panel according to an embodiment of the present invention.

FIG. 5 is a schematic top view showing a display panel according to another embodiment of the present invention.

FIG. 6A and FIG. 6B are schematic diagrams showing lead line structures of the display panel of FIG. 5.

FIG. 7A is a schematic enlarging diagram of a region R1 in FIG. 6A.

FIG. 7B is a schematic enlarging diagram of a region R2 in FIG. 6B.

### DESCRIPTION OF EMBODIMENTS

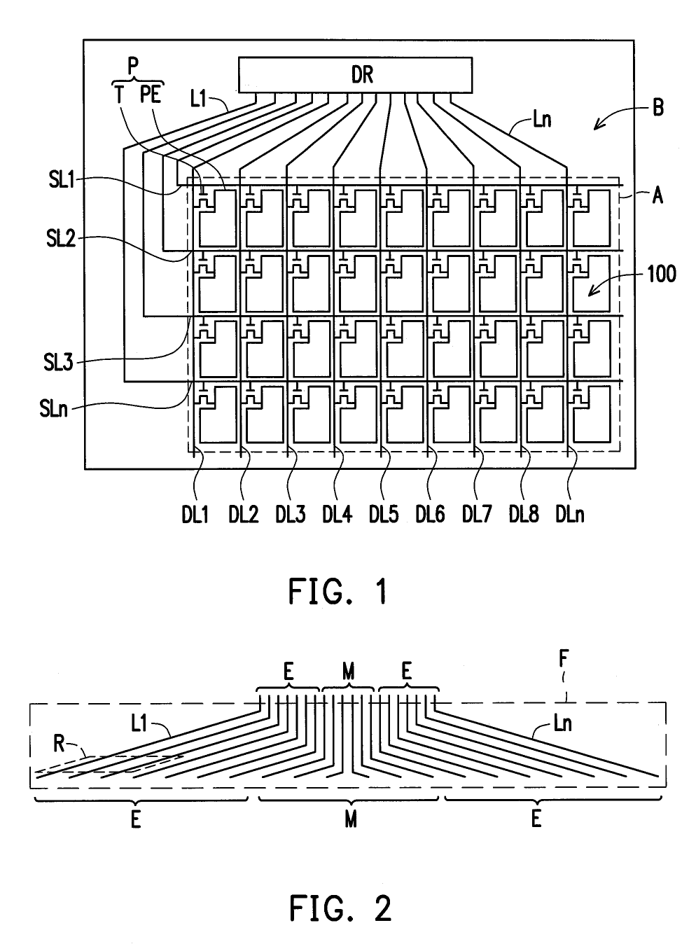

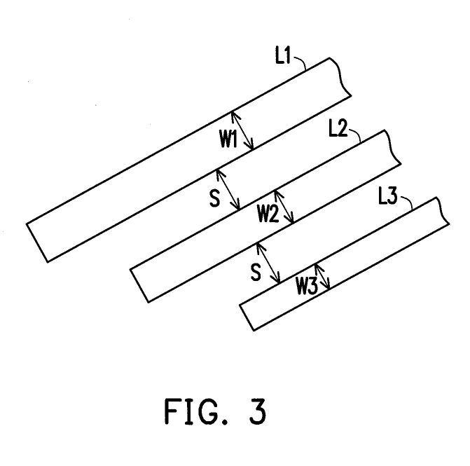

FIG. 1 is a schematic top view showing a display panel according to an embodiment of the present invention. FIG. 2 is a schematic diagram showing a lead line structure of the display panel of FIG. 1. Referring to FIG. 1 and FIG. 2, a display panel has of the present embodiment has a display region A and a non-display region B and includes a pixel array 100, at least one driving device DR and a plurality of lead lines L1˜Ln.

The pixel array 100 is disposed on a substrate and disposed in the display region A. In the embodiment, the pixel array 100 comprises a plurality of scan lines SL1˜SLn, a plurality of data lines DL1˜DLn and a plurality of pixel units P.

The scan lines SL1˜SLn cross over the data lines DL1˜DLn, and an insulation layer is sandwiched between the scan lines SL1˜SLn and the data lines DL1˜DLn. That is to say, extension directions of the data lines DL1˜DLn are not parallel to extension directions of the scan lines SL1˜SLn. Preferably, the extension directions of the data lines DL1˜DLn are perpendicular to the extension directions of the scan lines SL1˜SLn. In addition, the scan lines SL1˜SLn and the data lines DL1˜DLn are in different layers. In consideration of electrical conductivity, the data lines DL1˜DLn and the scan lines SL1˜SLn are often made of metal materials. However, the invention is not limited thereto. According to other embodiments of the invention, the scan lines SL1˜SLn and the data lines DL1˜DLn can also be made of other conductive materials. The metal material includes, for example, an alloy, metal nitride, metal oxide, metal oxynitride, another appropriate material, or a layer in which the metal material and any other conductive material are stacked to each other.

Each pixel unit P includes an active device T and a pixel electrode PE. The active device T can be a bottom-gate TFT or a top-gate TFT and includes a gate, a channel, a source, and a drain. Each of the pixel units P is electrically connected one of the scan lines SL1˜SLn and one of the data lines DL1˜DLn. The active devices T are electrically connected to the pixel electrodes PE.

The driving device DR is disposed in the non-display region B. The driving device DR provides driving signals to the pixel array 100 so as to drive the pixel array 100 displaying an image. In the embodiment, the driving device DR is disposed at one side of the display region A, which should not be construed as a limitation to the invention. According to another embodiment, the driving device DR may be disposed at two sides of the display region A or disposed around the display region A.

The lead lines L1˜Ln are disposed on the substrate and disposed in the non-display region B. The lead lines L1˜Ln are electrically connected to the pixel array 100 and the driving device DR, such that the lead lines L1˜Ln transmit the driving signals to the pixel array 100 from the driving device DR. In addition, the lead lines L1˜Ln are electrically connected to the scan lines SL1˜SLn and the data lines DL1˜DLn. According to the embodiment, since the scan lines SL1˜SLn and the data lines DL1˜DLn are disposed in different film layers, the lead lines L1˜Ln are disposed in suitable film layers according to the positions of the scan lines SL1˜SLn and the data lines DL1˜DLn.

The lead lines L1˜Ln are arranged into at least one fan-out structure F (as shown in FIG. 2) between the pixel array 100 and the driving device DR. Generally, the spaces between the adjacent scan lines and the spaces between the adjacent data lines in the pixel array 100 are larger than the spaces between contacts of the driving device DR, and thus the lead lines L1˜Ln electrically connected with the pixel array 100 and the driving device DR are arranged into the fan-out structure F. Moreover, the lengths of the lead lines L1˜Ln are not identical, namely, the lengths of the lead lines in an edge region E of the fan-out structure F is larger than or identical to the lengths of the lead lines in a middle region M of the fan-out structure F. In order to reduce signal delay differences between the lead lines L1˜Ln, the lead lines L1˜Ln are designed to have a new structure.

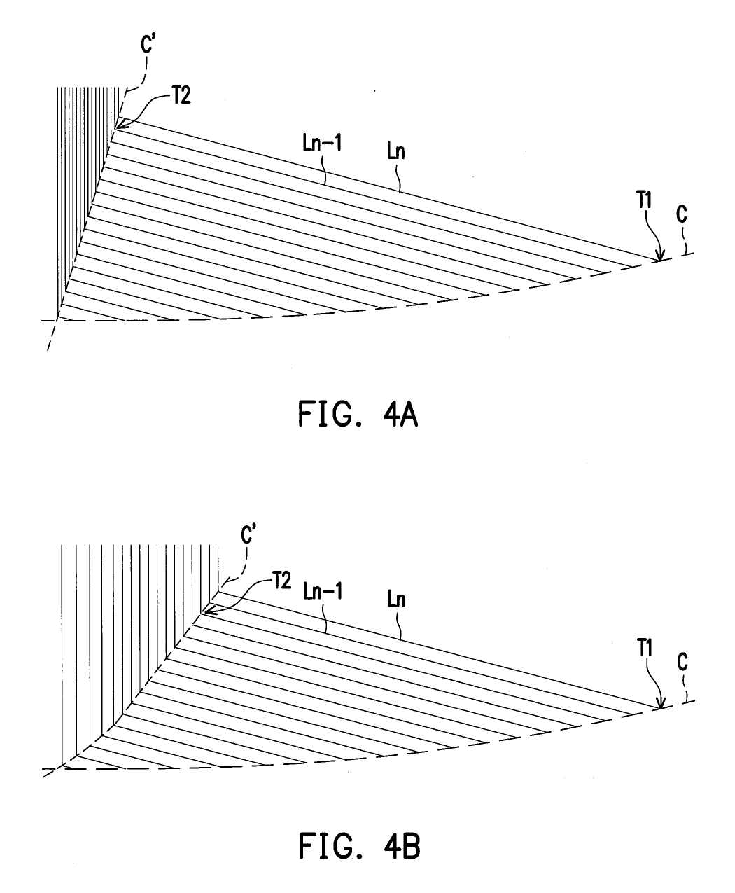

FIG. 3 is a schematic enlarging diagram of a region R in FIG. 2. As shown in FIG. 2 and FIG. 3, in the embodiment, the lead lines L1˜Ln respectively have a pitch P1, P2 . . . Pn-1, wherein the pitch Pn-1 Wn=Wn-1+S, n is an integer larger than 1, Wn-1 represents a line width of the lead line Ln-1, and S represents a space between the adjacent lead lines. Namely, the pitch between the lead line L1 and the lead line L2 is pitch P1, the pitch between the lead line L2 and the lead line L3 is pitch P2, the pitch between the lead line L3 and the lead line L4 is pitch P3. In particular, the pitches P1˜Pn-1 are not completely the same. For example, if the line width W1 is identical to the line width W2 and the line width W2 is not identical to the line width W3, the pitch P1 is identical to the pitch P2 and the pitch P2 is not identical to the pitch P3.

In the embodiment, the spaces S between the lead lines L1˜Ln in the fan-out structure F are identical. Generally, if the spaces S are smaller, it is favorable for reducing the overall area of the fan-out structure F.

In addition, the lead lines L1˜Ln-1 of the fan-out structure F respectively have a line width W1 , W2 . . . Wn-1. Namely, the lead line L1 has a line width W1, the lead line L2 has a line width W2, the lead line L3 has a line width W3, and the lead line Ln-1 has a line width Wn-1. In particular, the line width W1˜Wn-1 of the lead lines L1˜Ln-1 are not completely the same. According to the embodiment, the line widths of the lead lines in the middle region M of the fan-out structure F are smaller than the line widths of the lead lines in the edge region E of the fan-out structure F. Preferably, the line widths W1˜Wn-1 of the lead lines L1˜Ln-1 are increased from the middle region M toward the edge region E. For instance, the line width W1 of the lead line L1 is larger than or identical to the line width W2 of the lead lines L2, the line width W2 of the lead line L2 is larger than or identical to the line width W3 of the lead lines L3, and the line width Wn−2 of the lead line Ln-2 is larger than or identical to the line width Wn-1 of the lead lines Ln-1.

In the embodiment, the line width W1˜Wn-1 of the lead lines L1˜Ln-1 are not completely the same, and therefore the pitches P1˜Pn-1 of the lead lines L1˜Ln-1 in the fan-out structure F are not completely the same even though the spaces S between the lead lines L1˜Ln in the fan-out structure F are identical.

In addition, although the lengths of the lead lines in the edge region E of the fan-out structure F are larger than or identical to the lead lines in the middle region M of the fan-out structure F, the line widths W1˜Wn-1 of the lead lines L1˜Ln-1 are increased from the middle region M toward the edge region E. Namely, if the lead lines are closer to the middle region M of the fan-out structure F, the lead lines have smaller line widths; if the lead lines are closer to the edge region E of the fan-out structure F, the line widths of the lead lines are larger. Hence, the resistances between the lead lines are balanced, and thus signal delay differences between lead lines can be reduced.

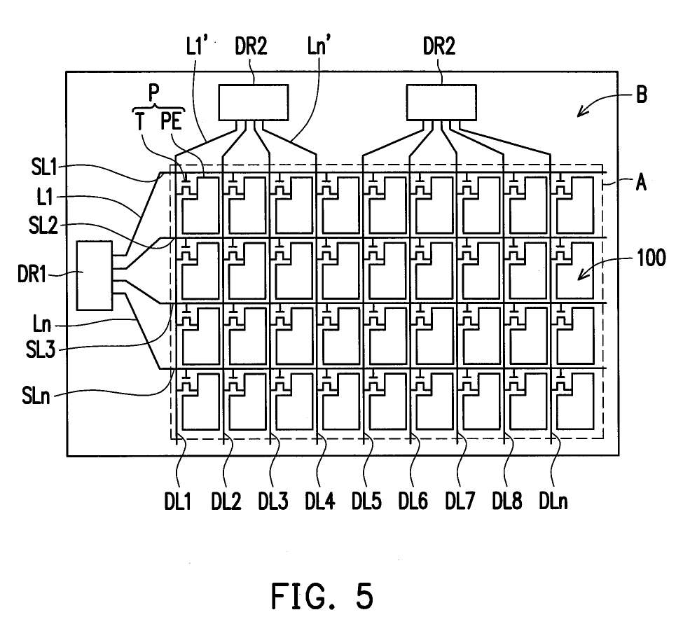

The above design for the lead lines L1˜Ln may also reduce the overall length of the fan-out structure F. In order to clearly describe the lead line structure, FIG. 4A only show the right half part of the fan-out structure F, and the left half part (not shown) of the fan-out structure is mirror symmetrical to and similar to the right half part. As shown in FIG. 4A, the lead lines L1˜Ln respectively have a first end T1 and a second end T2, the first ends T1 of the lead lines L1˜Ln are electrically connected to the pixel array 100, the second ends T2 of the lead lines L1˜Ln extend toward the driving device DR and are electrically connected to the driving device DR. If the pitches P1˜Pn-1 of the lead lines L1˜Ln-1 in the fan-out structure F are not completely the same, which satisfy the line widths W1˜Wn-1 (pitches P1˜Pn-1) of the lead lines L1˜Ln-1 are increased from the middle region M toward the edge region E, the first ends T1 of the lead lines L1˜Ln are arranged into a curve distribution (curve C) and the second ends T2 of the lead lines L1˜Ln are arranged into a straight line distribution (straight line C′). Since the first ends T1 of the lead lines L1˜Ln are arranged as the curve distribution (curve C), the overall length of the fan-out structure F is reduced. Namely, the fan-out structure F has a narrow and flat shape, which is favorable for being applied in slim border display panels. In addition to the curve distribution (curve C), the first ends T1 of the lead lines L1˜Ln may also be arranged into a saw-tooth distribution, a combination of a straight line distribution and a curve distribution, or other type distributions.

In another embodiment, in addition to the straight line distribution (straight line C′) as shown in FIG. 4A, the second ends T2 of the lead lines L1˜Ln may also be arranged into a curve distribution (curve C′) as shown in FIG. 4B, or a straight line distribution, or a combination of a straight line distribution and a curve distribution.

In the embodiment of FIG. 1, the driving device DR is disposed at one side of the display region A, and the scan line SL1˜SLn and the data lines DL1˜DLn are electrically connected to the driving device DR. According to another embodiment, driving devices are disposed at two sides of the display region A, and the scan line SL1˜SLn and the data lines DL1˜DLn are respectively electrically connected to the corresponding driving device.

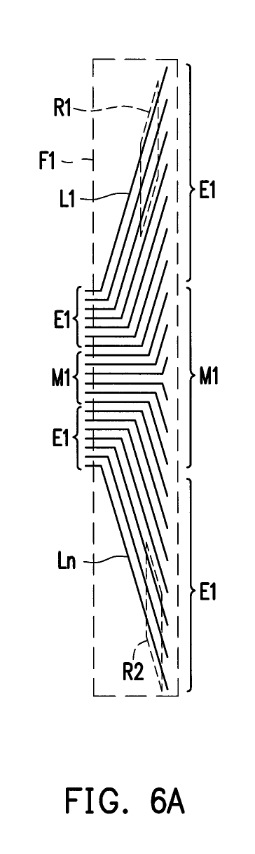

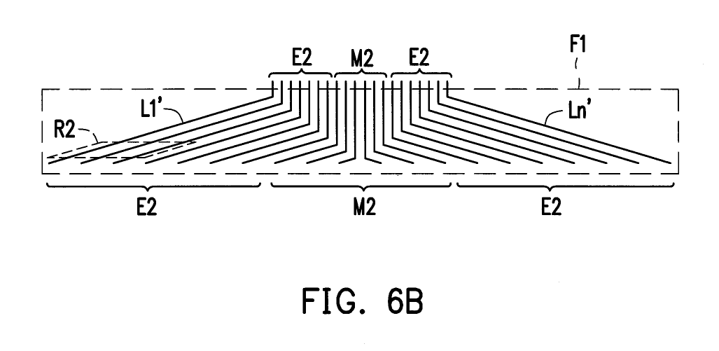

FIG. 5 is a schematic top view showing a display panel according to another embodiment of the present invention. FIG. 6A and FIG. 6B are schematic diagrams showing lead line structures of the display panel of FIG. 5. This embodiment is similar to the embodiment depicted in FIG. 1, and the same components indicated in FIG. 1 are denoted by the same numerals and are not repeated herein. Referring to FIG. 5, FIG. 6A and FIG. 6B, in the embodiment, the diving devices DR1, DR2 are disposed in the non-display region B and disposed at two sides of the display region A. The diving devices DR1, DR2 provide driving signals to the pixel array 100 so as to drive the pixel array 100 displaying an image.

The lead lines L1˜Ln and the lead lines L1′˜Ln′ are disposed in the non-display region B, the lead lines L1˜Ln are electrically connected to the pixel array 100 and the driving device DR1, and the lead lines L1′˜Ln′ are electrically connected to the pixel array 100 and the driving device DR2. According the embodiment, the lead lines L1˜Ln are electrically connected to the scan lines SL1˜SLn, and the lead lines LF˜Ln′ are electrically connected to the data lines DL1˜DLn. Similarly, since the scan lines SL1˜SLn and the data lines DL1˜DLn are disposed in different film layers, the lead lines L1˜Ln and the lead lines L1˜Ln′ are disposed in suitable film layers according to the positions of the scan lines SL1˜SLn and the data lines DL1˜DLn.

The lead lines L1˜Ln are arranged into at least one fan-out structure F1 between the pixel array 100 and the driving device DR1, as shown in FIG. 6A. The lead lines L1˜Ln′ are arranged into at least one fan-out structure F2 between the pixel array 100 and the driving device DR2, as shown in FIG. 6B. The lengths of the lead lines L1˜Ln are not identical and the lengths of the lead lines L1˜Ln′ are not identical. Namely, the lengths of the lead lines in an edge region E1 of the fan-out structure F1 is larger than or identical to the lengths of the lead lines in a middle region M1 of the fan-out structure F1. The lengths of the lead lines in an edge region E2 of the fan-out structure F2 is larger than or identical to the lengths of the lead lines in a middle region M2 of the fan-out structure F2. In order to reduce signal delay differences between the lead lines L1˜Ln of the fan-out structure F1 and reduce signal delay differences between the lead lines L1′˜Ln′ of the fan-out structure F2, the lead lines L1˜Ln of the fan-out structure Fl and the lead lines L1′˜Ln′ of the fan-out structure F2 are designed to have new structures.

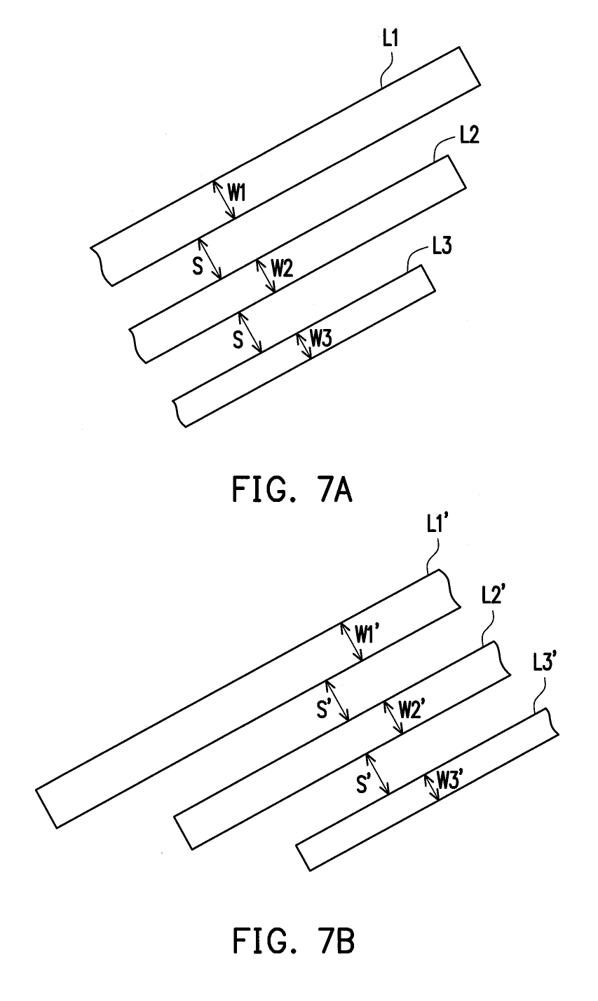

FIG. 7A is a schematic enlarging diagram of a region R1 in FIG. 6A. FIG. 7B is a schematic enlarging diagram of a region R2 in FIG. 6B. Referring to FIG. 6A and FIG. 7A, in the embodiment, the lead lines L1˜Ln-1 respectively have a pitch P1 , P2 . . . Pn-1, the pitch between the lead line L1 and the lead line L2 is P1=W1+S, W1 represents a line width of the lead line L1, and S represents a space between the adjacent lead lines. The pitch between the lead line L2 and the lead line L3 is P2=W2+S. The pitch between the lead line L3 and the lead line L4 is P3=W3+S. In particular, the pitches P1˜Pn-1 are not completely the same. Referring to FIG. 6B and FIG. 7B, in the embodiment, the lead lines L1′˜Ln-1′ respectively have a pitch P1′, P2′ . . . Pn-1′, the pitch between the lead line L1′ and the lead line L2′ is P1′=WF+S′, W1′ represents a line width of the lead line L1′, and S′ represents a space between the adjacent lead lines. The pitch between the lead line L2′ and the lead line L3′ is P2′=W2′+S′. The pitch between the lead line L3′ and the lead line L4′ is P3′=W3′+S′. In particular, the pitches P1′˜Pn-1′ are not completely the same.

For detail, the spaces S between the lead lines L1˜Ln in the fan-out structure F1 are identical, and the spaces S′ between the lead lines L1′˜Ln′ in the fan-out structure F2 are identical. Generally, if the spaces S1, S2′ are smaller, it is favorable for reducing the overall area of the fan-out structures F1, F2.

In addition, the lead lines L1˜Ln-1 of the fan-out structure F1 respectively have a line width W1, W2 . . . Wn-1. Namely, the lead line L1 has a line width W1, the lead line L2 has a line width W2, the lead line L3 has a line width W3, and the line width W1˜Wn-1 of the lead lines L1˜Ln-1 are not completely the same. According to the embodiment, the line widths of the lead lines in the middle region M1 of the fan-out structure F1 are smaller than line widths of the lead lines in the edge region E1 of the fan-out structure F1. Preferably, the line widths W1˜Wn-1 of the lead lines L1˜Ln-1 are increased from the middle region M1 toward the edge region E1. For instance, the line width W1 of the lead line L1 is larger than or identical to the line width W2 of the lead lines L2, and the line width W2 of the lead line L2 is larger than or identical to the line width W3 of the lead lines L3. Similarly, the lead lines L1′˜Ln-1′ of the fan-out structure F2 respectively have a line width W1′, W2′ . . . Wn-1′. Namely, the lead line L1′ has a line width W1′, the lead line L2′ has a line width W2′, the lead line L3′ has a line width W′3, and the line width W1′˜Wn-1′ of the lead lines L1′˜Ln-1′ are not completely the same. According to the embodiment, the line widths of the lead lines in the middle region M2 of the fan-out structure F2 are smaller than line widths of the lead lines in the edge region E12 of the fan-out structure F2. Preferably, the line widths W1′˜Wn-1′ of the lead lines L1′˜Ln-1′ are increased from the middle region M2 toward the edge region E2. For instance, the line width W1′ of the lead line L1′ is larger than or identical to the line width W2′ of the lead lines L2′, and the line width W2′ of the lead line L2′ is larger than or identical to the line width W3 of the lead lines L3.

In the embodiment, the line width W1˜Wn-1 of the lead lines L1˜Ln-1 of the fan-out structure F1 are not completely the same, and therefore the pitches P1˜Pn-1 of the lead lines L1˜Ln-1 in the fan-out structure F1 are not completely the same even though the spaces S between the lead lines L1˜Ln in the fan-out structure F1 are identical. For instance, if the width W1 is identical to the width W2 and the width W2 is not identical to the width W3, the pitch P1 is identical to the pitch P2 and the pitch P2 is not identical to the pitch P3. Similarly, the line width W1′˜Wn-1′ of the lead lines L1′˜Ln-1′ of the fan-out structure F2 are not completely the same, and therefore the pitches P1′˜Pn-1′ of the lead lines L1′˜Ln-1′ in the fan-out structure F2 are not completely the same even the spaces S′ between the lead lines L1′˜Ln′ in the fan-out structure F2 are identical. For instance, if the width W1′ is identical to the width W2′ and the width W2′ is not identical to the width W3′, the pitch P1′ is identical to the pitch P2′ and the pitch P2′ is not identical to the pitch P3′.

Usually, the lengths of the lead lines in the edge region E1 of the fan-out structure F1 are larger than or identical to the lead lines in the middle region M1 of the fan-out structure F1, and the lengths of the lead lines in the edge region E2 of the fan-out structure F2 are larger than or identical to the lead lines in the middle region M2 of the fan-out structure F2. In the embodiment, the line widths W1˜Wn-1 of the lead lines L1˜Ln-1 are increased from the middle region M1 toward the edge region E1, and the line widths W1′˜Wn-1′ of the lead lines L1′˜Ln-1′ are increased from the middle region M2 toward the edge region E2. Therefore, the resistances between the lead lines L1˜Ln and the resistances between the lead lines L1′˜Ln′ are balanced, such that signal delay differences between lead lines L1˜Ln and signal delay differences between the lead lines L1′˜Ln′ can be reduced.

In addition, since the line widths W1˜Wn-1 (pitches P1˜Pn-1) of the lead lines L1˜Ln-1 are increased from the middle region M1 toward the edge region E1, the ends of the lead lines L1˜Ln are arranged into a curve distribution (similar to the curve C shown in FIG. 4A and FIG. 4B). Since the line widths W1′˜Wn-1′(pitches P1′˜Pn-1′) of the lead lines L1′˜Ln-1′ are increased from the middle region M2 toward the edge region E2, the ends of the lead lines L12˜Ln2 are arranged into a curve distribution (similar to the curve C shown in FIG. 4A and FIG. 4B). In the embodiment, because the ends of the lead lines L1˜Ln and the ends of the lead lines L1′˜Ln′ are arranged into a curve distribution (curve C) respectively, the overall lengths of the fan-out structures F1, F2 are reduced. Namely, the fan-out structures F1, F2 have a narrow and flat shape, which is favorable for being applied in slim border display panels.

In light of the foregoing, the pitches of the plurality of lead lines in the fan-out structure are not completely the same. Preferably, the pitches of the plurality of lead lines in the fan-out structure are increased from the middle region toward the edge region, and the spaces between the adjacent lead lines are identical. Therefore, signal delay differences between the lead lines in the edge region and the lead lines in the middle of the fan-out structure can be decreased. In addition, the lead line structure in the embodiments may further reduce the overall length of the lead line structure, so as to being beneficial to be applied in the slim border display panels.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A display panel having a display region and a non-display region, comprising:
a pixel array, disposed in the display region;
at least one driving device, disposed in the non-display region; and
a plurality of lead lines, disposed in the non-display region and electrically connected to the pixel array and the driving device, wherein the lead lines are arranged into at least one fan-out structure between the pixel array and the driving device, and
a pitch Pn-1=Wn-1+S, Pn-1 represents the distance between (n-1)th and nth lead line, n is an integer larger than 1, Wn-1 represents a line width of the (n-1)th lead line, S represents a space between the adjacent lead lines, and the pitches P1˜Pn-1 of the plurality of lead lines are not completely the same.

2. The display panel as claimed in claim 1, wherein the spaces S between the lead lines in the fan-out structure are identical.

3. The display panel as claimed in claim 1, wherein the fan-out structure has a middle region and an edge region besides the middle region, and the line widths of the lead lines in the middle region are smaller than the line widths of the lead lines in the edge region.

4. The display panel as claimed in claim 3, wherein the line widths of the lead lines are increased from the middle region toward the edge region.

5. The display panel as claimed in claim 1, wherein each of the lead lines of the fan-out structure has a first end and a second end, the first ends of the lead lines are electrically connected to the pixel array, the second ends of the lead lines are electrically connected to the driving device, and the first ends of the lead lines are arranged into a curve distribution, a saw-tooth distribution, or a combination of a straight line distribution and a curve distribution.

6. The display panel as claimed in claim 5, wherein the second ends of the lead lines are arranged into a straight line distribution, a curve distribution, or a combination of a straight line distribution and a curve distribution.

7. The display panel as claimed in claim 1, wherein the pixel array comprises:
a plurality of scan lines and a plurality of data lines; and
a plurality of pixel units, each of the pixel units being electrically connected to one of the scan lines and one of the data lines.

8. The display panel as claimed in claim 7, wherein the lead lines are electrically connected to the scan lines and the data lines.

9. The display panel as claimed in claim 7, wherein parts of the lead lines are electrically connected to the scan lines, and the other parts of the lead lines are electrically connected to the data lines.

10. A lead line structure, comprising:
a substrate; and
a plurality of lead lines, disposed on the substrate and arranged into at least one fan-out structure, wherein
a pitch Pn-1=Wn-1+S, Pn-1 represents the distance between (n-1)th and nth lead line, n is an integer larger than 1, Wn-1 represents a line width of the (n-1)th lead line, S represents a space between the adjacent lead lines, and the pitches P1˜Pn-1 of the plurality of lead lines are not completely the same.

11. The lead line structure as claimed in claim 10, wherein the spaces S between the lead lines in the fan-out structure are identical.

12. The lead line structure as claimed in claim 10, wherein the fan-out structure has a middle region and an edge region besides the middle region, and line widths of the lead lines in the middle region are smaller than line widths of the lead lines in the edge region.

13. The lead line structure as claimed in claim 12, wherein the line widths of the lead lines are increased from the middle region toward the edge region.

14. A lead line structure, comprising:
a substrate;
a first lead line, disposed on the substrate;
a second lead line, disposed on the substrate and adjacent to the first lead line; and
a third lead line, disposed on the substrate and adjacent to the second lead line, wherein
a first pitch between the first lead line and the second lead line is P1=W1+S, a second pitch between the second lead line and the third lead line is P2=W2+S, W1 represents a line width of the first lead line, W2 represents a line width of the second lead line, S represents a space between the adjacent lead lines, and the first pitch P1 is different from the second pitch P2.

15. The lead line structure as claimed in claim 14, further comprising:
a fourth lead line, disposed on the substrate and adjacent to the third lead line wherein
a third pitch between the third lead line and the fourth lead line is P3=W3+S, W3 represents a line width of the third lead line, and the second pitch P2 is the same with the third pitch P3.

16. The lead line structure as claimed in claim 14, wherein the spaces S between the lead lines in the fan-out structure are identical.
